(19) United States
(12) Patent Application Publication
(10) Pub. No.: US 2007/0018941 A1
(43) Pub. Date: Jan. 25, 2007

(54) DRIVER FOR LIGHT SOURCE HAVING INTEGRATED PHOTOSENSITIVE ELEMENTS FOR DRIVER CONTROL

(75) Inventors: James C. Moyer, San Jose, CA (US); Michael R. Hsing, Saratoga, CA (US); Jean-Francois Daviet, Fremont, CA (US)

Correspondence Address: PERKINS COIE LLP, POST OFFICE BOX 1208, SEATTLE, WA, 98111-1208, US

(73) Assignee: Monolithic Power Systems, Inc., Los Gatos, CA (US)

(21) Appl. No.: 11/457,712

(22) Filed: Jul. 14, 2006

Related U.S. Application Data
(63) Continuation of application No. 10/578,535.
(60) Provisional application No. 60/517,306, filed on Nov. 3, 2003.

(51) Int. Cl. H01S 5/00; G09G 3/36

(52) U.S. Cl. 345/102

(57) ABSTRACT

A method for automatically adjusting the intensity of a lighting element based on feedback from internal and external sources of light is disclosed herein. A photosensitive element senses ambient light and transmits an electrical signal proportional to the intensity of the ambient light to a driver. The driver automatically adjusts the intensity of the lighting element based on this feedback to provide optimal conditions for the application. In addition, the lighting element transmits an electrical signal proportional to the intensity of the light from the lighting element to a driver. The driver further adjusts the intensity of the lighting element based on this feedback to provide optimal conditions for the application.

### PRIORITY CLAIM

This application is a continuation of U.S. application No. 10/578,535 filed May 3, 2006, which claims priority to PCT Application No. US2004/035594, filed Oct. 26, 2004, and now pending, which claims the benefit of U.S. Provisional Application No. 60/517,306, filed Nov. 3, 2003.

### TECHNICAL FIELD

The following disclosure relates generally to photosensitive systems and, more particularly, to an automated process for adjusting the intensity of a lighting element based on feedback from both internal and external lighting elements.

### BACKGROUND

Integrated circuits (ICs) are widely used to efficiently control the power delivered to a lighting element. Integrated circuits are typically used to control the power delivered to a lighting element in situations where limited physical space makes the usage of a set of discrete components difficult, battery operation requires efficient power conversion for longer unplugged autonomy, environmental regulations require efficient in-use power conversion and very low stand-by power consumption, or where the cost of the set of discrete components is an issue.

Integrated circuits developed for the specific task of delivering power to a lighting element are often referred to as “drivers” of the lighting element. For example, integrated circuit drivers are commonly used to deliver power to cold cathode fluorescent lights (CCFLs), electroluminescent (EL) lights, and LED (light emitting diode) lighting devices, which, in one application, may be used to provide backlight for liquid crystal displays (LCDs). These LCDs can be found in many size-sensitive user applications such as mobile electronics (e.g., laptop computers, pocket computers, and cell phones), flat panel monitors, and televisions.

As energy-saving environmental regulations become more stringent, these IC drivers are finding their way into more mainstream applications such as general lighting. The range of applications for drivers is thus expanding, for example, to include hot cathode fluorescent lights (the traditional “neon lamp”) and low-intensity nightlight devices.

In addition to mainstream applications, IC drivers may be used to adjust the intensity of the backlight for various applications. For instance, a lighting element of a computer display may be dimmed in dark, indoor conditions, to provide optimum viewing for a user. The same lighting element may be brightened in sunny, outdoor conditions. Traditionally, a user must adjust the intensity of the backlight manually.

### SUMMARY

A method for automatically detecting and adjusting the lighting level of a display screen is presented. Ambient light reaches a photosensitive element. The photosensitive element transmits an electrical signal proportional to the intensity of the ambient light to the driver, which in turn automatically adjusts the power delivered to an internal lighting element to provide for optimal functioning of the user application.

Light from the internal lighting element reaches a photosensitive element. The photosensitive element transmits an electrical signal proportional to the intensity of the light from the lighting element to the driver, which in turn adjusts the power delivered to the internal lighting element to provide for optimal functioning of the user application.

### BRIEF DESCRIPTION OF THE DRAWINGS

FIGS. 1 is a schematic diagram illustrating a top down view of a monolithic integrated circuit.

FIG. 2 is a schematic diagram illustrating a top down view of the photosensitive areas of the monolithic integrated circuit.

FIG. 3 is a diagram illustrating a section for receiving ambient light in accordance with one embodiment of the invention.

FIG. 4 is a diagram illustrating a section for receiving light from a lighting element in accordance with one embodiment of the invention.

FIG. 5 is a diagram illustrating a section for receiving both ambient light and light from a lighting element in accordance with one embodiment of the invention.

FIG. 6 is a flow diagram illustrating the basic operating principle of an integrated light driver having photosensitive feedback capability.

### DETAILED DESCRIPTION

The invention will now be described with respect to various embodiments. The following description provides specific details for a thorough understanding of, and enabling description for, these embodiments of the invention. However, one skilled in the art will understand that the invention may be practiced without these details. In other instances, well-known structures and functions have not been shown or described in detail to avoid unnecessarily obscuring the description of the embodiments of the invention.

It is intended that the terminology used in the description presented below be interpreted in its broadest reasonable manner, even though it is being used in conjunction with a detailed description of certain specific embodiments of the invention. Certain terms may even be emphasized below; however, any terminology intended to be interpreted in any restricted manner will be overtly and specifically defined as such in this Detailed Description section.

The photosensitive elements described herein may be of any type normally placed on an integrated circuit, such as photodiodes, pinned photodiodes, photogates, and charge coupled devices. In one example, a photodiode can be formed simply as an n-type region formed in a p-type region. Incident light may cause charge to flow across the photodiode. This charge can be read as a current or voltage using known techniques. The photosensitive elements can be formed on an integrated circuit, and, in accordance with one embodiment of the present invention, formed on the same integrated circuit as the driver.

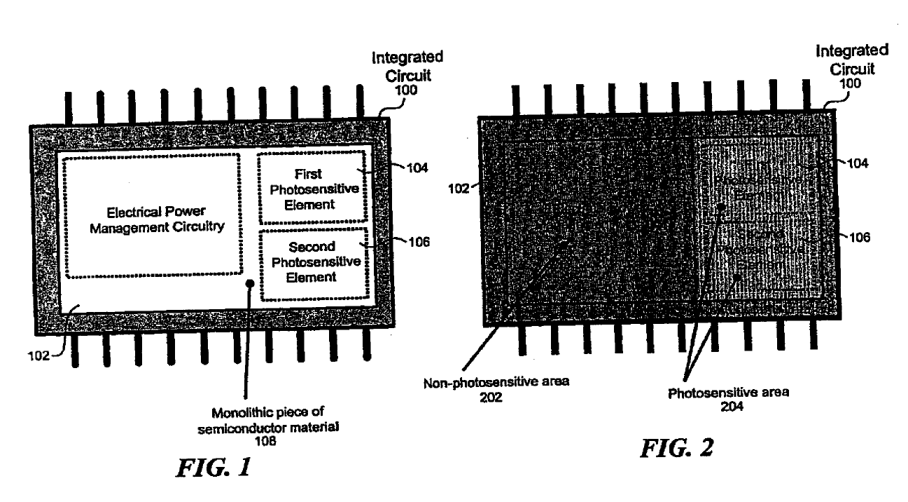

FIG. 1 illustrates a top down view of a monolithic integrated circuit 100. A monolithic piece of semiconductor material 108 encloses an electrical power management circuitry 102, a first photosensitive element 104, and a second photosensitive element 106. Photosensitive elements, such as photodiodes, are widely used in electronic devices to gather information on the quality and quantity of light emitted by a given source. In this embodiment, the two photosensitive elements have been integrated onto the same monolithic circuit die as the electrical power management circuitry 102 or the driver. The integration of the photosensitive elements with the electrical power management circuitry 102 can provide significant cost, size, and power consumption advantages over traditional, discrete component-based feedback solutions. The two photosensitive elements provide information on local light conditions while the electrical power management circuitry 102 controls or drives the intensity of a lighting element in response to information on local light conditions to enhance performance for a given user application.

The performance enhancement of a given user application may be quantified by, but not limited to, one or more benefits. User experience may be improved by providing consistent lighting of the user application regardless of the level of ambient light or the state of the user application itself (such as being “cold” or “warm”). The overall energy efficiency of the user application may be improved by continually optimizing the power delivered to the lighting element in response to the level of ambient light or the state of the user application itself In addition, the lifetime of the lighting element may be improved by reducing unnecessarily elevated power loads which in turn reduces the overall wear of the lighting element. Also, the reliability of the overall user application may be improved by monitoring and comparing the lighting elements performance over time to a known reference, thus allowing the trigger of an early warning when the lighting element is reaching its end-of-life. The above embodiments illustrate several benefits of enhancing the performance of a given user application and are not meant to be all encompassing or definitive. Other benefits could be presented or available in addition to the benefits above.

In addition to providing several key benefits, a fully integrated driver with photosensitive elements provides several advantages over discrete, non-integrated photosensitive systems. By avoiding the use of a separate discrete integrated circuit to drive power to the lighting elements, a fully integrated driver with photosensitive elements can reduce cost, size, and power consumption.

In an alternative embodiment, a non-monolithic integrated circuit can be utilized to implement an integrated light driver having photosensitive feedback capability. A non-monolithic integrated circuit consists of two photosensitive elements integrated with the electrical power management circuitry or driver on one integrated circuit but lacking the monolithic piece of semiconductor material to enclose the disparate elements. In yet another alternative embodiment, two or more integrated circuits can be assembled in the same package to implement an integrated light driver having photosensitive feedback capability. The above embodiments illustrate two ways in which an integrated light driver having photosensitive feedback capability can be implemented and are not meant to be all encompassing or definitive. Other options could be presented or available in addition to the two embodiments above.

FIG. 2 illustrates a top down view of the photosensitive areas of the integrated circuit 100. A photosensitive area 204 includes both the first photosensitive element 104 and the second photosensitive element 106. The top encapsulation of the photosensitive area is mostly transparent, allowing for both photosensitive elements to be receptive to external sources of light. The photosensitive elements can provide information on local light conditions to the electrical power management circuitry 102 so that it can adjust the lighting element to provide optimal performance. A non-photosensitive area 202 includes the electrical power management circuitry 102.

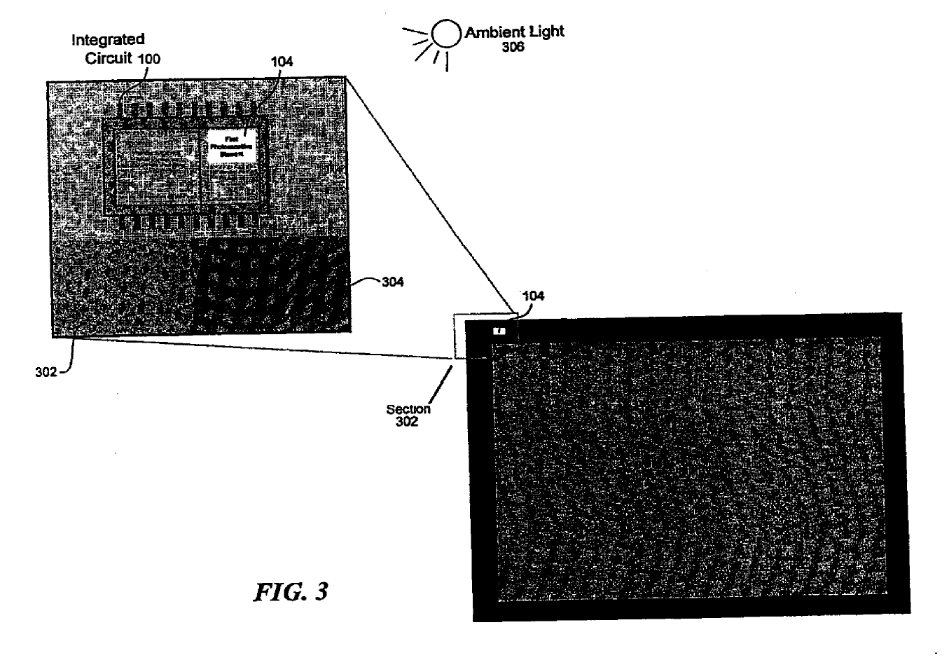

FIG. 3 shows one possible application of the present invention. In this application, a backlight display, such as that used for computer monitors, is shown. FIG. 3 illustrates a section 302 for receiving ambient light 306 in accordance with one embodiment of the invention. The section 302 represents a section of a display 304 that is shown in expanded view. The section 302 is an optically transparent opening made in the display 304 and aligned with one of the photosensitive elements. The section contains the integrated circuit 100 and the first photosensitive element 104. The first photosensitive element 104 receives ambient light 306 from a light source that is external to the display 304. The first photosensitive element 104 provides an electrical signal proportional to the intensity of the ambient light 306 to the electrical power management circuitry 102, which controls the power delivered to the lighting element. The electrical power management circuitry 102 uses the electrical signal to adjust the electrical power delivered to the lighting element, so as to provide lighting suitable for the user application. In one instance, the lighting element would be dimmed in dark indoor conditions and brightened in sunny outdoor conditions. In an alternative embodiment, the section and integrated circuit orientation may face the rear of the display 304 as opposed to the front, so as to optimize the contrast between the display and the actual field of view of the user.

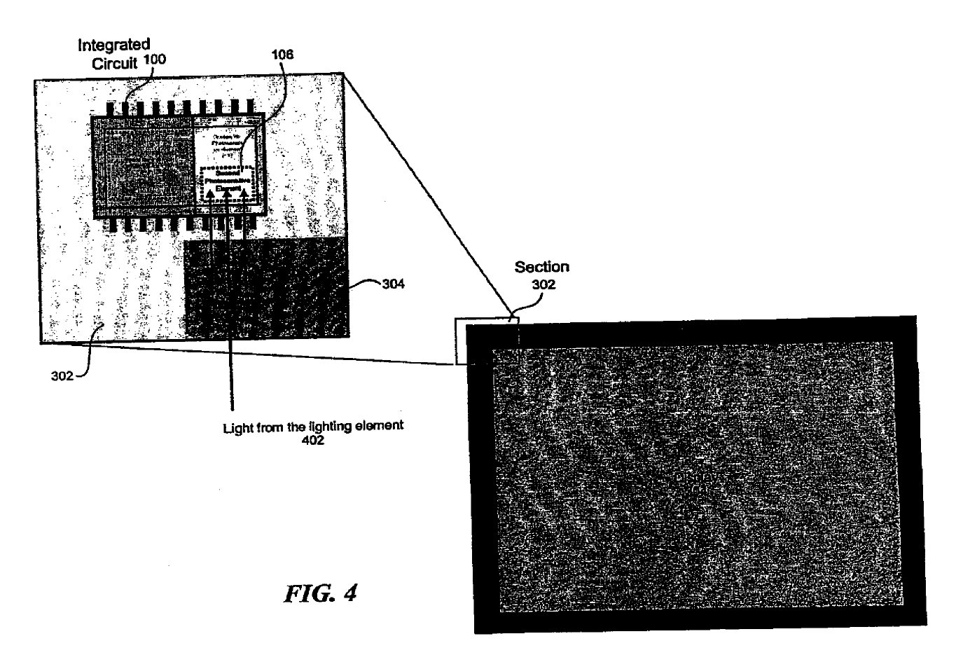

FIG. 4 illustrates a section 302 for receiving light from an internal lighting element 402 in accordance with one embodiment of the invention. The section 302, which is a part of the display 304, contains the integrated circuit 100 and the second photosensitive element 106. Light from the lighting element 402 is guided onto the second photosensitive element 106, either directly or through a simple light-guiding structure. The lighting element may include, but is not limited to, one or more of the following elements: a CCFL (cold cathode fluorescent light), an array of LED's (light emitting diodes), an electroluminescent (EL) device, an organic LED, a halogen lamp, an incandescent lamp, a laser-based device, and a plasma-based device. Other devices may be used as a lighting element. Once the second photosensitive element 106 receives the light from the lighting element 402, the second photosensitive element 106 provides an electrical signal proportional to the intensity of the light from the lighting element 402 to the electrical power management circuitry 102. The electrical power management circuitry 102 uses the information to adjust the electrical power provided to the lighting element, so as to automatically provide lighting suitable for the user application. In one instance, the electrical power management circuitry 102 could provide higher power upon startup if the lighting element is a CCFL, which is traditionally dimmer during the first few minutes of operation. Likewise, more power could be fed to the lighting element as it ages and tends to lose its light-emitting efficiency. Finally, comparing the actual steady-state brightness of the lighting element with a set reference could provide an early failure warning to the user.

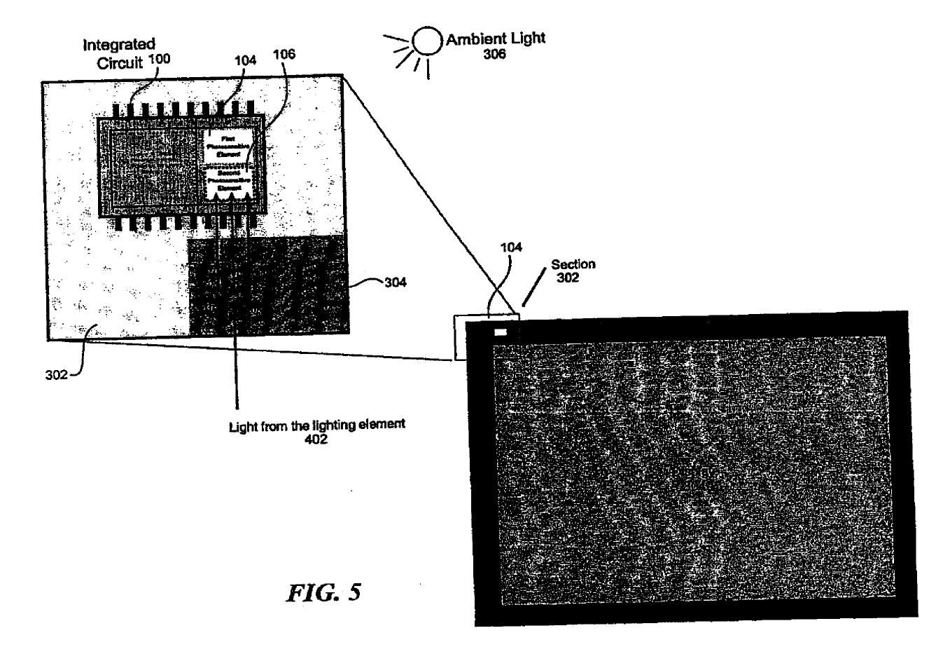

FIG. 5 illustrates a section 302 for receiving both ambient light 306 and light from a lighting element 402 in accordance with one embodiment of the invention. The section 302, situated within a display 304, contains an integrated circuit 100, a first photosensitive element 104, and a second photosensitive element 106. The first photosensitive element 104 receives ambient light 306 from an external source and provides an electrical signal proportional to the intensity of the ambient light 306 to the electrical power management circuitry 102. The electrical power management circuitry 102 then adjusts the electrical power provided to the lighting element based on this information to automatically provide lighting suitable for the user application. The second photosensitive element 106 receives light from the internal lighting element 402 and provides an electrical signal proportional to the intensity of the light from the lighting element 402. The electrical power management circuitry 102 then adjusts the electrical power provided to the lighting element based on this information to automatically provide lighting suitable for the user application. The two photosensitive elements are photo-isolated from one another to avoid interference between the two light feedback paths: one from the external environment and the other from the internal lighting element. The photo-isolation of the two photosensitive elements can be achieved by simple mechanical means.

In an alternative embodiment, the light collected on the second photosensitive element 106 from the internal lighting element could be used to detect the working conditions of the lighting element and to detect an early failure warning. In another alternative embodiment, the user application could be a portable or wearable electronic device such as, but not limited to, a laptop computer, a pocket computer, a personal digital assistant, a cell phone, a digital camera, a global positioning system (GPS), a camcorder, a personal music player, a gaming device, or video goggles. In yet another alternative embodiment, the user application could be a stationary (e.g., in a home) or otherwise embedded (e.g., in an automobile) electronic device such as, but not limited to, a computer monitor, a flat panel television, a gaming console, a general purpose lamp, a low intensity night light, an advanced remote control unit, a GPS, a dashboard or a part thereof, or a heads-up display system.

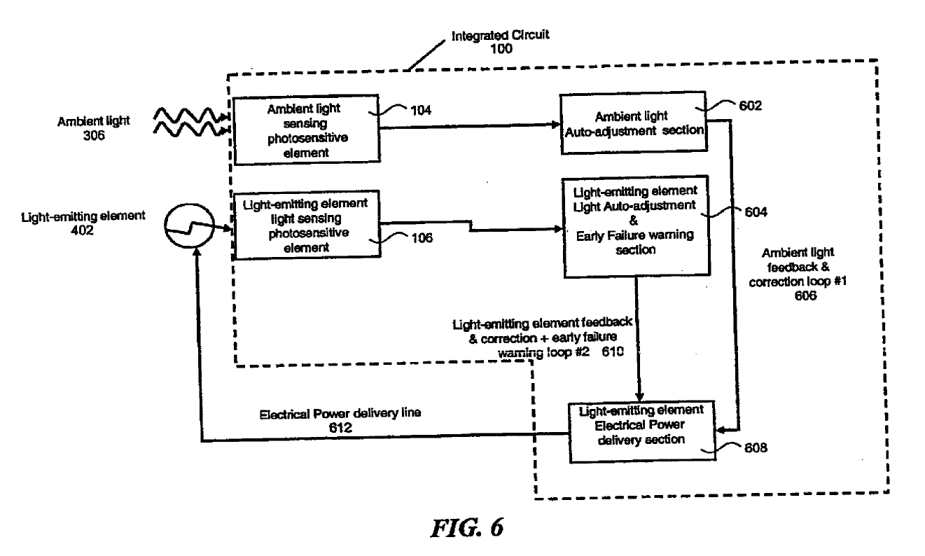

FIG. 6 illustrates the basic operating principle of an integrated light driver having photosensitive feedback capability. Ambient light 306 reaches an ambient light sensing photosensitive element 104. The ambient light sensing photosensitive element 104 leads to an ambient light auto-adjustment section 602. The ambient light auto-adjustment section 602 transmits an electrical signal proportional to the intensity of the ambient light 306 to a light-emitting element electrical power delivery section 608 through an ambient light feedback and correction loop #1 (606). Once the light-emitting element electrical power delivery section 608 has received the electrical signal from the ambient light auto-adjustment section 602, the light-emitting element electrical power delivery section 608 can adjust the power delivered to the light-emitting element 402 through an electrical power delivery line 612. The light-emitting element 402 transmits light to a light-emitting element light sensing photosensitive element 106, which leads to a light-emitting element light auto-adjustment and early failure warning section 604. The light-emitting element light auto-adjustment and early failure warning section 604 transmits an electrical signal proportional to the intensity of the light from the light-emitting element 402 to the light-emitting element electrical power delivery section 608 through a light-emitting element feedback and correction and early failure warning loop #2 (610). The light-emitting element electrical power delivery section 608 adjusts the power delivered to the light-emitting element 402 through an electrical power delivery line 612.

In one embodiment, the implementation includes both light-emitting element brightness adjustment loops #1 (606) and #2 (610). In an alternative embodiment, the implementation includes either light-emitting element brightness adjustment loop #1 (606) or light-emitting element brightness adjustment loop #2 (610). In yet another alternative embodiment, the integrated circuit may combine several distinct monolithic sections in one package.

The above detailed descriptions of embodiments of the invention are not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize.

Words in the above detailed description using the singular or plural number may also include the plural or singular number respectively. Additionally, the words “herein,” “above,” “below,” and words of similar import, when used in this application, shall refer to this application as a whole and not to any particular portions of this application. When the claims use the word “or” in reference to a list of two or more items, that word covers all of the following interpretations of the word: any of the items in the list, all of the items in the list, and any combination of the items in the list.

The teachings of the invention provided herein can be applied to other systems, not necessarily the system described herein. These and other changes can be made to the invention in light of the detailed description. The elements and acts of the various embodiments described above can be combined to provide further embodiments.

These and other changes can be made to the invention in light of the above detailed description. While the above description details certain embodiments of the invention and describes the best mode contemplated, no matter how detailed the above description appears in text, the invention can be practiced in many ways. Details of configurations, functions, etc. may vary considerably in implementation details, while still being encompassed by the invention disclosed herein. As noted above, particular terminology used when describing certain features, or aspects of the invention should not be taken to imply that the terminology is being re-defined herein to be restricted to any specific characteristics, features, or aspects of the invention with which that terminology is associated. In general, the terms used should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention.

We claim:

1. An apparatus, comprising: a controller capable of receiving, at least in part, a brightness level signal indicative of a brightness level of a display, said controller also capable of controlling the brightness of said display, based at least in part on said brightness level signal.

2. The apparatus of claim 1, wherein: said controller further capable of receiving, at least in part, an ambient light signal indicative of ambient light in the vicinity of said display, said controller further capable of controlling the brightness of said display, based at least in part on said ambient light signal.

3. The apparatus of claim 1, further comprising a display brightness sensor capable of generating said brightness level signal.

4. The apparatus of claim 2, further comprising an ambient light sensor capable of generating said ambient light signal.

5. The apparatus of claim 1, further comprising an inverter power supply capable of being controlled by said inverter controller, said inverter power supply also being capable of generating a controllable power signal to said display.

6. The apparatus of claim 1, wherein: said display being selected form an LCD panel, plasma displays, field emission displays and light emitting diode displays.

7. The apparatus of claim 1, wherein: said controller further capable of receiving, at least in part, a default brightness signal indicative of a default brightness of said display, inverter controller further capable of controlling the brightness of said display, based at least in part on said default.

8. A system, comprising: a display; and a controller capable of receiving, at least in part, a brightness level signal indicative of a brightness level of said display, said controller also capable of controlling the brightness of said display, based at least in part on said brightness level signal.

9. The system of claim 8, wherein: said controller further capable of receiving, at least in part, an ambient light signal indicative of ambient light in the vicinity of said display, said controller further capable of controlling the brightness of said display, based at least in part on said ambient light signal.

10. The system of claim 8, further comprising a display brightness sensor capable of generating said brightness level signal.

11. The system of claim 9, further comprising an ambient light sensor capable of generating said ambient light signal.

12. The system of claim 8, further comprising an inverter power supply capable of being controlled by said inverter controller, said inverter power supply also being capable of generating a controllable power signal to said display.

13. The system of claim 8, wherein: said display being selected form an LCD panel, plasma displays, field emission displays and light emitting diode displays.

14. The system of claim 8, wherein: said controller further capable of receiving, at least in part, a default brightness signal indicative of a default brightness of said display, said controller further capable of controlling the brightness of said display, based at least in part on said default.

15. A method, comprising: generating a signal indicative of a display brightness level; and controlling the brightness of said display, based at least in part on said signal indicative of a display brightness level.

16. The method of claim 15, further comprising: generating a signal indicative of an ambient light level; and controlling the brightness of said display, based at least in part on said signal indicative of an ambient light level.

17. The method of claim 15, further comprising: generating a signal indicative of a default panel brightness; and controlling the brightness of said display, based at least in part on said signal indicative of a default panel brightness.

18. A module, comprising: a controller capable of receiving, at least in part, a brightness level signal indicative of a brightness level of a display and further capable of generating a control signal indicative of said brightness level; and power supply circuitry capable of receiving said control signal from said controller and further capable of delivering power to said display, based at least in part on said control signal.

19. The module as claimed in claim 18, wherein: said controller is further capable of receiving, at least in part, an ambient brightness signal, wherein said control signal is indicative, at least in part, of said ambient brightness.

20. The module as claimed in claim 18, wherein: said controller is further capable of receiving, at least in part, a default brightness signal, wherein said control signal is indicative, at least in part, of said default brightness.

21. The module as claimed in claim 18, wherein: said controller and said power supply circuitry are disposed on a printed circuit board.

22. The module as claimed in claim 18, wherein: said display is selected from LCD displays, plasma displays, field emission displays and light emitting diode displays

23. A method, comprising: generating a first signal indicative of a display brightness level; and generating a second signal indicative of an ambient light level; and controlling the brightness of said display, based on at least one of said first or second signals.

24. The method of claim 23, further comprising: generating a third signal indicative of a default panel brightness; and controlling the brightness of said display, based at least in part on said third signal.

25. The method of claim 23, wherein: said first signal being generated in a first time period, said second signal generated in a second time period, and further comprising multiplexing said first and second signals and controlling the brightness of said display using said first signal in said first time interval and said second signal in said second time interval.

26. An apparatus, comprising: a sensor capable of generating a first signal indicative of a display brightness level in a first time period, and a second signal indicative of an ambient light level in a second time period; and a controller capable of receiving said first and second signals, and further capable of controlling the brightness of said display based on at least one of said first and second signals.
